(19) United States
(12) Patent Application Publication
(10) Pub. No.: US 2023/0147634 A1
(43) Pub. Date: May 11, 2023

(54) Method for operating a sensor

(71) Applicant: Robert Bosch GmbH, Stuttgart (DE)

(72) Inventor: Michael Roelleke, Leonberg-Hoefingen (DE)

(21) Appl. No.: 18/053,064

(22) Filed: Nov. 7, 2022

(30) Foreign Application Priority Data
Nov. 8, 2021 (DE) 10 2021 212 524.7

(51) Int. Cl. G01P 1/00; G01P 15/00; G06N 3/08

(52) U.S. Cl. CPC G01P 1/00; G01P 15/00; G06N 3/08

(57) ABSTRACT

A method is for operating a sensor. Influences on the sensor are detected and compensated for by an artificial neural network (ANN). The influences on the sensor are described by information from surroundings of the sensor, and an output signal of the sensor is linked in the ANN to further data representing the information from the surroundings of the sensor, such that a compensated output signal is obtained.

The invention relates to a method for operating a sensor and an arrangement for carrying out the method.

### PRIOR ART

A sensor is to be understood as a technical component which is designed to detect physical or chemical properties and/or the material nature of its surroundings in a qualitative manner or in a quantitative manner as a measured variable.

It should be noted that, in the case of sensors, deviations in the behavior result from small variations during manufacture and due to non-linear effects, which are reflected in measurement inaccuracies. These are typically described in the specification, but often cannot be compensated for. Firstly, the physical relationships are not fully known and, secondly, there are hardly any possibilities to determine the variations. A common method is calibration using the ambient temperature, during which the sensitivity of the sensor is corrected.

Within the scope of the proposed method, the use of an artificial neural network (ANN) is described. An ANN is a network constructed from artificial neurons Like artificial neurons, a network of this kind has a biological model, i.e. a natural neural network, which in turn represents an interconnection of neurons in the nervous system of a living being. When considering ANNs, the focus is on abstraction or modeling of information processing, in particular. The basis for the model of an ANN is an artificial neuron. In a network of artificial neurons, said neurons can approximate complex functions, learn tasks, and solve problems in which explicit modeling is difficult or impossible to carry out. The biological model of an artificial neuron is a nerve cell. It can process a plurality of inputs and respond accordingly by being activated.

In particular in the field of image processing, ANNs have become widely accessible in recent years, which, inter alia, has led to significant development in this field. Different applications are possible for ANNs. However, it is not sufficient to train any kind of ANN with data sets. It should also be noted here that the recognition accuracy of an ANN depends very strongly on the training data. The larger the network, the more data are needed.

In addition, the following points also need to be taken into account: Firstly, in the so-called “hidden” layers, there is the problem of interpreting the parameters and, secondly, although there are methods for determining the learning progress using test data, no conclusions regarding the probability of unknown data being recognized can be drawn.

### DISCLOSURE OF THE INVENTION

Against this background, a method according to claim 1 and an arrangement according to claim 9 are proposed. Embodiments can be found in the dependent claims and in the description.

The proposed method is used to operate a sensor, in particular a sensor in a motor vehicle. In the method, influences on the sensor are detected and compensated for by an artificial neural network (ANN). Influences on the sensor are external effects on the sensor or on the function of the sensor which affect its functioning and thus also an output signal delivered by the sensor. An influence can be produced, for example, by the temperature in the surroundings of the sensor.

The influences on the sensor can be described by means of information from the surroundings of the sensor. For example, one item of information is the temperature.

In the method, the output signal of the sensor is linked in the ANN to further data representing the information from the surroundings of the sensor, such that a compensated output signal is obtained. This is typically output by the ANN.

The described method is used, for example, in so-called MEMS sensors (MEMS: microelectromechanical system). MEMSs are components that combine logic elements and micromechanical structures in a chip. They can process mechanical and electrical information.

A solution is thus proposed herein which makes it possible to improve the performance of sensors through the use of an ANN. It is assumed here that all “essential” influences on the sensor can be detected and that these influences can be compensated for by means of an ANN. Consequently, a very error-free output signal can be generated.

Typically, a sensor might not recognize its own inaccuracy. As a result, it requires additional information from its surroundings. Information of this kind will be available in the future thanks to the so-called Internet of Things. This makes it possible for a new behavior or a new situation to be recognized with significant recognition errors and for the network to subsequently learn these data when surveilling or monitoring the data. As a result, the reaction to similar situations is improved.

For example, sensors for automated driving are designed to have redundant structures on account of the requirements for functional safety. As a result, it is possible, in particular also in the case of deviations between the sensor information, to detect the situation and to record training data in order to then learn said data during rest phases. In this way, properties which change over time can be detected and the behavior of the ANN is optimized.

The proposed method combines the knowledge of the design and the function of a sensor with an ANN. It is based on the assumption that a sensor element is influenced by information from its surroundings. Currently, in many cases, only the temperature is used and the accuracy is increased by means of calibration during manufacture. The use of an ANN now makes it possible to learn different effects via the network and, when the temperature is exclusively used, it can result in the above-mentioned temperature compensation. In the process, by using lots of information, the ANN can achieve an improvement in accuracy by learning. It is hereby important to also process historical data of these ambient signals in addition to the current ambient signals of the sensor, such as temperature, cross-influences, and operating voltages. Said historical data may include, for example, significant overloads during operation and also events which occur immediately before the measurement time.

It is important to identify the necessary signals, which can vary depending on the sensor, and to make them available to the ANN in a suitable manner. The structure of the ANN is not important here, but the depth of the network, i.e. the number of layers, should be selected such that a learning optimum can be achieved.

The proposed arrangement is used to carry out the method described herein and is implemented, for example, in a piece of hardware and/or software. The arrangement can be integrated in a control device, for example, of a motor vehicle or designed as such. The above-described ANN can be incorporated in this arrangement.

Further advantages and embodiments of the invention can be found in the description and the accompanying drawings.

Of course, the features mentioned above and those still to be explained below can be used not only in the respectively specified combinations, but also in other combinations or alone, without departing from the scope of the present invention.

### BRIEF DESCRIPTION OF THE DRAWINGS

FIG. 1 shows a module for processing information within the scope of the proposed method.

FIG. 2 is a schematic representation of a design of the overall structure.

FIG. 3 shows a motor vehicle having an arrangement for carrying out the proposed method.

### EMBODIMENTS OF THE INVENTION

The invention is represented schematically in the drawings on the basis of embodiments and is described below with reference to the drawings.

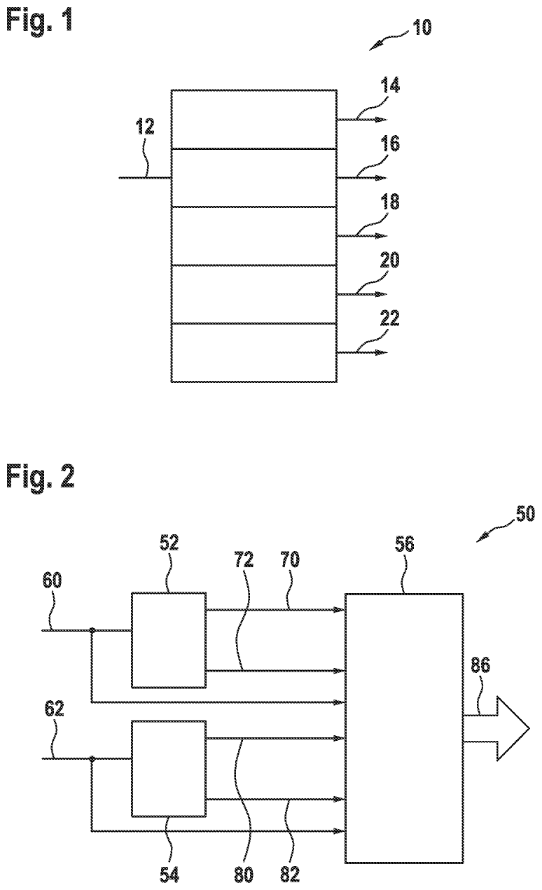

FIG. 1 shows a module 10 for processing information, as can be carried out within the scope of the proposed method. In this case, an input 12 for the module 10 is an item of information I or a course of said item of information I.

The item of information I is any variable that changes over time. The item of information can relate, for example, to the operating voltage, the housing temperature, the ambient temperature, the power consumption of the module or the device, and output variables of other sensors. The items of information I are processed in the module 10 in such a way that a reference to history is created and compaction is achieved. t₀ is the current time and tₓ is in the past.

Output variables are:

I₁ 14 by calculating the difference (ΔI (t₀, tₓ)) between the current I at the time t₀ and at the time tₓ,
I₂ 16 by forming a window integral with length t₁,
I₃ 18 by applying a low-pass filter with cutoff frequency f_{Grenz} and order,
I₄ 20 by applying a high-pass filter with cutoff frequency f_{Grenz} and order, and

### Iₙ 22.

Any desired methods from signal processing can be used here. It is important that each output I₁, . . . Iₙ contains one item of information. The parameters of the methods used, such as f_{Grenz}, order, selection tₓ, depend on the application and need to be determined. The determination can, for example, also be done using AI structures (AI: artificial intelligence) that perform parameter optimization.

FIG. 2 is a schematic representation of the design of the overall structure of an arrangement, which is denoted as a whole by the reference numeral 50. The representation shows a first module 52 and a second module 54 as well as an artificial neural network (ANN) 56. These modules 52, 54 correspond to the module 10 from FIG. 1.

Input variables are an output signal S 60 of a sensor and a signal I 62, which carries data representing further information. The signal S 60 is split into signals S₁ 70 to Sₙ 72, for example according to the information preparation according to FIG. 1. The signal I 62 is also split into signals I₁ 80 to Iₙ 82. The ANN, which records and evaluates the different signals, outputs a compensated output signal 86, i.e. the influences on the output signal S 60 have been taken into account or compensated for in the compensated output signal.

When splitting the output signal S 60, it should be noted that it is important to use properties from the past to predict the future. There are several options for this, such as mean value, window integral, filter, etc. There is currently no specification for this. Effects which are addressed therewith are, for example in MEMS acceleration sensors, e.g. the fading of mechanical shocks.

The proposed method thus links the output signal S 60 of a sensor to additional items of information I 62, which are provided, for example, by further sensors and thus by other structures. It is also conceivable for the sensor to be enhanced such that additional elements therein generate this information.

The type and quantity of information required to achieve an improvement depends, in particular, on the specific application.

The items of information I 62 can still be linked to the “past” by means of mathematical methods. These mathematical methods include, in addition to derivation, higher-order derivatives, signal filtering, and window integrals having different window lengths. This function is implemented, for example, by the modules 52 and 54.

These signal processing methods offer the ANN 56 a large quantity of information which has an influence on the output signal S 60. One possible form of information processing is shown by way of example in FIG. 1.

During development of the sensors, the optimum information is selected and offered to the ANN for the purpose of training. Known methods can be used to train the ANN.

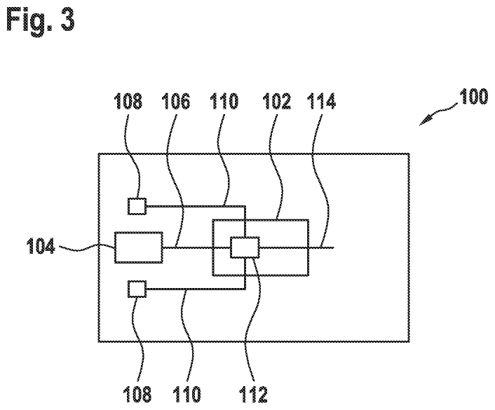

FIG. 3 shows a motor vehicle 100 in which an embodiment of the arrangement for carrying out the method is provided, which arrangement is denoted as a whole by the reference numeral 102. In the motor vehicle 100, in addition to the arrangement 102, a sensor 104 is shown which supplies an output signal 106 which is to be processed accordingly such that a signal which is as free of errors as possible is obtained. To this end, further data 110 are acquired via further sensors 108, which further data relate to information, in particular information relating to typically technical variables from the surroundings of the sensor 104. These variables, for example the temperature, have an influence on the sensor 104 or on the functioning thereof and thus also on the output signal 106 delivered.

An artificial neural network 112 is provided in the arrangement 102 and links the output signal 106 of the sensor 104 to the further data 110 of the further sensors 108 and, in this way, can compensate for the influence of said data 110 on the output signal 106. A compensated output signal 114 can then be output.

1. A method for operating a sensor included in a device, comprising:
detecting and compensating for influences on the sensor using an artificial neural network (ANN);
describing the influences on the sensor based on information from surroundings of the sensor;
linking an output signal of the sensor in the ANN to further data representing the information from the surroundings of the sensor, such that a compensated output signal is obtained; and
operating the device based on the compensated output signal.

2. The method according to claim 1, wherein the information from the surroundings of the sensor, which information is represented by the further data, is linked by mathematical methods.

3. The method according to claim 1, wherein the information from the surroundings of the sensor, which information is represented by the further data, is linked to a past time period by mathematical methods.

4. The method according to claim 2, wherein the mathematical methods include at least one of a derivation, higher-order derivatives, signal filtering, and window integrals having different window lengths.

5. The method according to claim 1, wherein the output signal of the sensor is split into a plurality of signals before the linking.

6. The method according to claim 1, wherein the further data relating to information from the surroundings of the sensor are provided via the Internet of Things.

7. The method according to claim 1, wherein information relating to historical information is taken into account.

8. The method according to claim 1, wherein the sensor includes a MEMS sensor.

9. An arrangement for operating a sensor, wherein the arrangement is configured to carry out the method according to claim 1.

10. The arrangement according to claim 9, wherein the arrangement includes the ANN.
